(19) United States
(12) Patent Application Publication
(10) Pub. No.: US 2013/0052806 A1
(43) Pub. Date: Feb. 28, 2013

(54) DEPOSITION SYSTEMS HAVING ACCESS GATES AT DESIRABLE LOCATIONS, AND RELATED METHODS

(71) Applicants: Ronald Thomas Bertram, JR., Mesa, AZ (US); Christiaan J. Werkhoven, Gilbert, AZ (US); Chantal Arena, Mesa, AZ (US); Ed Lindow, Scottsdale, AZ (US)

(72) Inventors: Ronald Thomas Bertram, JR., Mesa, AZ (US); Christiaan J. Werkhoven, Gilbert, AZ (US); Chantal Arena, Mesa, AZ (US); Ed Lindow, Scottsdale, AZ (US)

(73) Assignee: SOITEC, Crolles Cedex (FR)

(21) Appl. No.: 13/591,718

(22) Filed: Aug. 22, 2012

Related U.S. Application Data
(60) Provisional application No. 61/526,137, filed on Aug. 22, 2011.

(51) Int. Cl. C23C 16/458; B23P 11/00; H01L 21/20

(52) U.S. Cl. 438/478; 118/728; 137/15.01; 257/E21.09

(57) ABSTRACT

Deposition systems include a reaction chamber, and a substrate support structure disposed at least partially within the reaction chamber. The systems further include at least one gas injection device and at least one vacuum device, which together are used to flow process gases through the reaction chamber. The systems also include at least one access gate through which a workpiece substrate may be loaded into the reaction chamber and unloaded out from the reaction chamber. The at least one access gate is located remote from the gas injection device. Methods of depositing semiconductor material may be performed using such deposition systems. Methods of fabricating such deposition systems may include coupling an access gate to a reaction chamber at a location remote from a gas injection device.

### CROSS-REFERENCE TO RELATED APPLICATIONS

This application claims the benefit of U.S. Provisional Patent Application Ser. No. 61/526,137, filed Aug. 22, 2011. The subject matter of this application is related to the subject matter of U.S. patent application Ser. No. ______ (Attorney Docket No. 3356-10680.1US), which was filed on even date herewith in the name of Bertram et al. and entitled “DEPOSITION SYSTEMS INCLUDING A PRECURSOR GAS FURNACE WITHIN A REACTION CHAMBER, AND RELATED METHODS,” and to the subject matter of U.S. patent application Ser. No. ______ (Attorney Docket No. 3356-10708.1US), which was filed on even date herewith in the name of Bertram and entitled “DIRECT LIQUID INJECTION FOR HALIDE VAPOR PHASE EPITAXY SYSTEMS AND METHODS,” the entire disclosure of each of which application is incorporated herein in its entirety by this reference.

### FIELD

Embodiments of the invention generally relate to systems for depositing materials on substrates, and to methods of making and using such systems. More particularly, embodiments of the invention relate to atomic layer deposition (ALD) methods for depositing III-V semiconductor materials on substrates and to methods of making and using such systems.

### BACKGROUND

Chemical vapor deposition (CVD) is a chemical process that is used to deposit solid materials on substrates, and is commonly employed in the manufacture of semiconductor devices. In chemical vapor deposition processes, a substrate is exposed to one or more reagent gases, which react, decompose, or both react and decompose in a manner that results in the deposition of a solid material on the surface of the substrate.

One particular type of CVD process is referred to in the art as vapor phase epitaxy (VPE). In VPE processes, a substrate is exposed to one or more reagent vapors in a reaction chamber, which react, decompose, or both react and decompose in a manner that results in the epitaxial deposition of a solid material on the surface of the substrate. VPE processes are often used to deposit III-V semiconductor materials. When one of the reagent vapors in a VPE process comprises a hydride vapor, the process may be referred to as a hydride vapor phase epitaxy (HVPE) process.

HVPE processes are used to form III-V semiconductor materials such as, for example, gallium nitride (GaN). In such processes, epitaxial growth of GaN on a substrate results from a vapor phase reaction between gallium chloride (GaCl) and ammonia (NH₃) that is carried out within a reaction chamber at elevated temperatures between about 500° C. and about 1,000° C. The NH₃ may be supplied from a standard source of NH₃ gas.

In some methods, the GaCl vapor is provided by passing hydrogen chloride (HCl) gas (which may be supplied from a standard source of HCl gas) overheated liquid gallium (Ga) to form GaCl in situ within the reaction chamber. The liquid gallium may be heated to a temperature of between about 750° C. and about 850° C. The GaCl and the NH₃ may be directed to (e.g., over) a surface of a heated substrate, such as a wafer of semiconductor material. U.S. Pat. No. 6,179,913, which issued Jan. 30, 2001 to Solomon et al., discloses a gas injection system for use in such systems and methods, the entire disclosure of which patent is incorporated herein by reference.

In such systems, it may be necessary to open the reaction chamber to atmosphere to replenish the source of liquid gallium. Furthermore, it may not be possible to clean the reaction chamber in situ in such systems.

To address such issues, methods and systems have been developed that utilize an external source of a GaCl₃ precursor, which is directly injected into the reaction chamber. Examples of such methods and systems are disclosed in, for example, U.S. Patent Application Publication No. US 2009/0223442 A1, which published Sep. 10, 2009 in the name of Arena et al., the entire disclosure of which publication is incorporated herein by reference.

Previously known deposition systems often include an access gate through which workpiece substrates may be loaded into the reaction chamber and unloaded out from the reaction chamber after processing. Such access gates are often located in a front gas injection manifold of the deposition system, which is used to inject precursor gases into the reaction chamber.

### BRIEF SUMMARY

This summary is provided to introduce a selection of concepts in a simplified form, such concepts being further described in the detailed description below of some example embodiments of the invention. This summary is not intended to identify key features or essential features of the claimed subject matter, nor is it intended to be used to limit the scope of the claimed subject matter.

In some embodiments, the present disclosure includes deposition systems that comprise a reaction chamber, and a substrate support structure disposed at least partially within the reaction chamber and configured to support a workpiece substrate within the reaction chamber. The reaction chamber may be defined by a top wall, a bottom wall, and at least one side wall. The systems further include at least one gas injection device for injecting one or more process gases including at least one precursor gas into the reaction chamber at a first location, and a vacuum device for drawing the one or more process gases through the reaction chamber from the first location to a second location and for evacuating the one or more process gases out from the reaction chamber at the second location. The systems also include at least one access gate through which a workpiece substrate may be loaded into the reaction chamber and onto the substrate support structure and unloaded from the substrate support structure out from the reaction chamber. The at least one access gate is located remote from the first location at which the at least one gas injection device injects one or more process gases into the reaction chamber.

In additional embodiments, the present disclosure includes methods of depositing semiconductor material on a workpiece substrate using a deposition system. In accordance with such methods, a workpiece substrate may be loaded into a reaction chamber and onto a substrate support structure through at least one access gate. One or more process gases may be caused to flow into the reaction chamber through at least one gas injection device located remote from the at least one access gate. The one or more process gases may include at least one precursor gas. The one or more process gases may be evacuated out from the reaction chamber through at least one vacuum device located on an opposing side of the substrate support structure from the at least one gas injection device. A surface of the workpiece substrate may be exposed to the one or more process gases as they flow from the at least one gas injection device to the at least one vacuum device, and semiconductor material may be deposited on the surface of the workpiece substrate. The workpiece substrate may be unloaded out from the reaction chamber through the at least one access gate.

In yet further embodiments, the present disclosure includes methods of fabricating deposition systems. For example, a reaction chamber may be formed that includes a top wall, a bottom wall, and at least one side wall. A substrate support structure for supporting at least one workpiece substrate may be provided at least partially within the reaction chamber. At least one gas injection device may be coupled to the reaction chamber at a first location. The at least one gas injection device may be configured for injecting one or more process gases including at least one precursor gas into the reaction chamber at the first location. At least one vacuum device may be coupled to the reaction chamber at a second location. The at least one vacuum device may be configured for drawing the one or more process gases through the reaction chamber from the first location to the second location, and for evacuating the one or more process gases out from the reaction chamber at the second location. At least one access gate may be coupled to the reaction chamber at a location remote from the first location. The at least one access gate may be configured to enable a workpiece substrate to be loaded into the reaction chamber and onto the substrate support structure, and unloaded from the substrate support structure out from the reaction chamber through the at least one access gate.

### BRIEF DESCRIPTION OF THE DRAWINGS

The present disclosure may be understood more fully by reference to the following detailed description of example embodiments, which are illustrated in the appended figures in which:

FIG. 1 is a cut-away perspective view schematically illustrating an example embodiment of a deposition system that includes an access gate through which workpiece substrates may be inserted into and removed out from a reaction chamber, the access gate being located remotely from a location at which process gases are injected into the reaction chamber;

FIG. 2 is a perspective view of a front exterior surface of a gas injection device of the deposition system of FIG. 1;

FIG. 3 is a cross-sectional side view of the an internal precursor gas furnace of the deposition system of FIG. 1;

FIG. 4 is a top plan view of one of the generally plate-shaped structures of the precursor gas furnace of FIGS. 1 and 2;

FIG. 5 is a perspective view of the internal precursor gas furnace of the deposition system of FIG. 1;

FIG. 6 is a cut-away perspective view schematically illustrating another example embodiment of a deposition system that includes an access gate located remotely from a location at which process gases are injected into the reaction chamber, but including an external precursor gas injector instead of an internal precursor gas furnace;

FIG. 7 is a top plan view schematically illustrating another example embodiment of a deposition system of the present disclosure that includes an access gate located remotely from a location at which process gases are injected into the reaction chamber;

FIG. 8 is a cut-away perspective view schematically illustrating another example embodiment of a deposition system that includes an access gate located remotely from a location at which process gases are injected into the reaction chamber, wherein the chamber includes more than one gas flow channel therein; and

FIG. 9 is a top plan view schematically illustrating another example embodiment of a deposition system, similar to the deposition system of FIG. 1, including three precursor gas furnaces.

### DETAILED DESCRIPTION OF EMBODIMENTS OF THE INVENTION

The illustrations presented herein are not meant to be actual views of any particular system, component, or device, but are merely idealized representations that are employed to describe embodiments of the present invention.

As used herein, the term “III-V semiconductor material” means and includes any semiconductor material that is at least predominantly comprised of one or more elements from group IIIA of the periodic table (B, Al, Ga, In, and Ti) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, InGaNP, etc.

As used herein, the term “remote” means and includes separated by an interval in space that is greater than a usual separation (e.g., located far away), not proximate. For example, in the context of spatial distances within the deposition system of the current disclosure, a separation between two entities of greater than 100 millimeters, greater than 200 millimeters, or even greater than 300 millimeters would be interpreted as two entities that are remote from one another.

Improved gas injectors have recently been developed for use in methods and systems that utilize an external source of a GaCl₃ precursor that is injected into the reaction chamber, such as those disclosed in the aforementioned U.S. Patent Application Publication No. US 2009/0223442 A1. Examples of such gas injectors are disclosed in, for example, U.S. Patent Application Ser. No. 61/157,112, which was filed on Mar. 3, 2009 in the name of Arena et al., the entire disclosure of which application is incorporated herein in its entirety by this reference. As used herein, the term “gas” includes gases (fluids that have neither independent shape nor volume) and vapors (gases that include diffused liquid or solid matter suspended therein), and the terms “gas” and “vapor” are used synonymously herein.

Embodiments of the present invention include, and make use of, deposition systems that include an access gate for loading workpiece substrates into a reaction chamber and/or unloading workpiece substrates from the reaction chamber. The access gate is disposed at a location remote from a location at which one or more process gases, which may include one or more precursor gases, are injected into the reaction chamber.

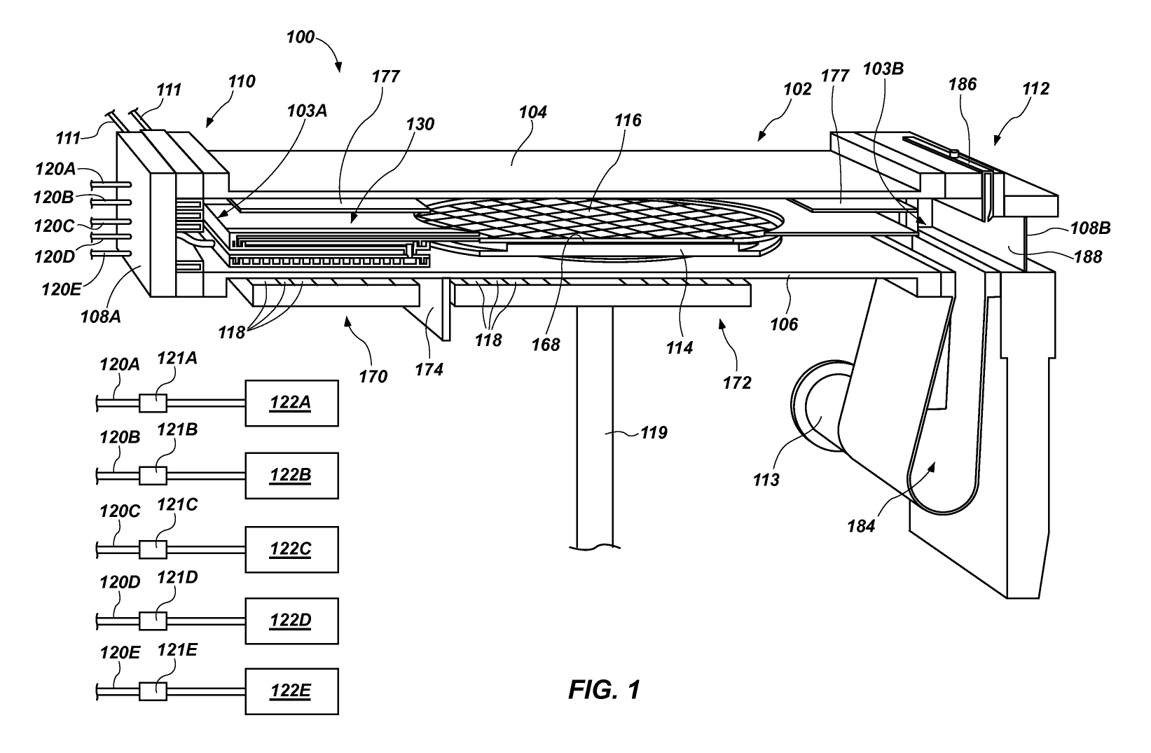

FIG. 1 illustrates a deposition system 100, which includes an at least substantially enclosed reaction chamber 102. In some embodiments, the deposition system 100 may comprise a CVD system, and may comprise a VPE deposition system (e.g., an HVPE deposition system).

The reaction chamber 102 may be defined by a top wall 104, a bottom wall 106, and one or more side walls. One or more of the side walls may be defined by a component or components of subassemblies of the deposition system. For example, a first side wall 108A may comprise a component of a gas injection device 110 used for injecting one or more process gases into the reaction chamber 102, and a second side wall 108B may comprise a component of a venting and loading subassembly 112 used for venting process gases out from the reaction chamber 102, as well as for loading substrates into the reaction chamber 102 and unloading substrates out from the reaction chamber 102. Stated another way, the gas injection device 110 may be configured to inject one or more process gases through the side wall 108A of the reaction chamber 102.

In some embodiments, the reaction chamber 102 may have the geometric shape of an elongated rectangular prism, as shown in FIG. 1. In some such embodiments, the gas injection device 110 may be located at a first end of the reaction chamber 102, and the venting and loading subassembly may be located at an opposing second end of the reaction chamber 102. In other embodiments, the reaction chamber 102 may have another geometric shape.

The deposition system 100 includes a substrate support structure 114 (e.g., a susceptor) configured to support one or more workpiece substrates 116 on which it is desired to deposit or otherwise provide semiconductor material within the deposition system 100. For example, the workpiece substrates 116 may comprise dies or wafers. The deposition system 100 further includes heating elements 118, which may be used to selectively heat the deposition system 100 such that an average temperature within the reaction chamber 102 may be controlled to within desirable elevated temperatures during deposition processes. The heating elements 118 may comprise, for example, resistive heating elements or radiant heating elements (e.g., heating lamps).

As shown in FIG. 1, the substrate support structure 114 may be coupled to a spindle 119, which may be coupled (e.g., directly structurally coupled, magnetically coupled, etc.) to a drive device (not shown), such as an electrical motor that is configured to drive rotation of the spindle 119 and, hence, the substrate support structure 114 within the reaction chamber 102.

In some embodiments, one or more of the top wall 104, the bottom wall 106, the substrate support structure 114, the spindle 119, and any other components within the reaction chamber 102 may be at least substantially comprised of a refractory ceramic material such as a ceramic oxide (e.g., silica (quartz), alumina, zirconia, etc.), a carbide (e.g., silicon carbide, boron carbide, etc.), a nitride (e.g., silicon nitride, boron nitride, etc.), or graphite coated with silicon carbide. As a non-limiting example, the top wall 104, the bottom wall 106, the substrate support structure 114, and the spindle 119 may comprise transparent quartz so as to allow thermal energy radiated by the heating elements 118 to pass there through and heat process gases within the reaction chamber 102.

The deposition system 100 further includes a gas flow system used to flow process gases through the reaction chamber 102. For example, the deposition system 100 may comprise at least one gas injection device 110 for injecting one or more process gases into the reaction chamber 102 at a first location 103A, and a vacuum device 113 for drawing the one or more process gases through the reaction chamber 102 from the first location 103A to a second location 103B and for evacuating the one or more process gases out from the reaction chamber 102 at the second location 103B. The gas injection device 110 may comprise, for example, a gas injection manifold including connectors configured to couple with conduits carrying one or more process gases from process gas sources.

With continued reference to FIG. 1, the deposition system 100 may include five gas inflow conduits 120A-120E that carry gases from respective process gas sources 122A-122E to the gas injection device 110. Optionally, gas valves (121A-121E) may be used to selectively control the flow of gas through the gas inflow conduits 120A-120E, respectively.

In some embodiments, at least one of the gas sources 122A-122E may comprise an external source of at least one of GaCl₃, InCl₃, or AlCl₃, as described in U.S. Patent Application Publication No. US 2009/0223442 A1. GaCl₃, InCl₃ and AlCl₃ may exist in the form of a dimer such as, for example, Ga₂Cl₆, In₂Cl₆ and Al₂Cl₆, respectively. Thus, at least one of the gas sources 122A-122F may comprise a dimer such as Ga₂Cl₆, In₂Cl₆ or Al₂Cl₆.

In embodiments in which one or more of the gas sources 122A-122E is or includes a GaCl₃ source, the GaCl₃ source may include a reservoir of liquid GaCl₃ maintained at a temperature of at least 100° C. (e.g., approximately 130° C.), and may include physical means for enhancing the evaporation rate of the liquid GaCl₃. Such physical means may include, for example, a device configured to agitate the liquid GaCl₃, a device configured to spray the liquid GaCl₃, a device configured to flow carrier gas rapidly over the liquid GaCl₃, a device configured to bubble carrier gas through the liquid GaCl₃, a device, such as a piezoelectric device, configured to ultrasonically disperse the liquid GaCl₃, and the like. As a non-limiting example, a carrier gas, such as He, N₂, H₂, or Ar, may be bubbled through the liquid GaCl₃, while the liquid GaCl₃ is maintained at a temperature of at least 100° C., such that the source gas may include one or more carrier gases in which precursor gas is conveyed.

The flux of precursor gas (e.g., GaCl₃) vapor through one or more of the gas inflow conduits 120A-120E may be controlled in some embodiments of the invention. For example, in embodiments in which a carrier gas is bubbled through liquid GaCl₃, the GaCl₃flux from the gas source 122A-122E is dependent on one or more factors, including for example, the temperature of the GaCl₃, the pressure over the GaCl₃, and the flow of carrier gas that is bubbled through the GaCl₃. While the mass flux of GaCl₃ can in principle be controlled by any of these parameters, in some embodiments, the mass flux of GaCl₃ may be controlled by varying the flow of the carrier gas using a mass flow controller.

In some embodiments, the one or more of the gas sources 122A-122E may be capable of holding about 25 kg or more of GaCl₃, about 35 kg or more of GaCl₃, or even about 50 kg or more of GaCl₃. For example, the GaCl₃ source my be capable of holding between about 50 and 100 kg of GaCl₃ (e.g., between about 60 and 70 kg). Furthermore, multiple sources of GaCl₃ may be connected together to form a single one of the gas sources 122A-122E using a manifold to permit switching from one gas source to another without interrupting operation and/or use of the deposition system 100. The empty gas source may be removed and replaced with a new full source while the deposition system 100 remains operational.

In some embodiments, the temperatures of the gas inflow conduits 120A-120E may be controlled between the gas sources 122A-122E and the reaction chamber 102. The temperatures of the gas inflow conduits 120A-120E and associated mass flow sensors, controllers, and the like may increase gradually from a first temperature (e.g., about 100° C. or more) at the exit from the respective gas sources 122A-122E up to a second temperature (e.g., about 150° C. or less) at the point of entry into the reaction chamber 102 in order to prevent condensation of the gases (e.g., GaCl₃ vapor) in the gas inflow conduits 120A-120E. Optionally, the length of the gas inflow conduits 120A-120E between the respective gas sources 122A-122E and the reaction chamber 102 may be about three feet or less, about two feet or less, or even about one foot or less. The pressure of the source gasses may be controlled using one or more pressure control systems.

In additional embodiments, the deposition system 100 may include less than five (e.g., one to four) gas inflow conduits and respective gas sources, or the deposition system 100 may include more than five (e.g., six, seven, etc.) gas inflow conduits and respective gas sources.

The one or more of the gas inflow conduits 120A-120E extend to the gas injection device 110. The gas injection device 110 may comprise one or more blocks of material through which the process gases are carried into the reaction chamber 102. One or more cooling conduits 111 may extend through the blocks of material. A cooling fluid may be caused to flow through the one or more cooling conduits 111 so as to maintain the gas or gases flowing through the gas injection device 110 by way of the gas inflow conduits 120A-120E within a desirable temperature range during operation of the deposition system 100. For example, it may be desirable to maintain the gas or gases flowing through the gas injection device 110 by way of the gas inflow conduits 120A-120E at a temperature less than about 200° C. (e.g., about 150° C.) during operation of the deposition system.

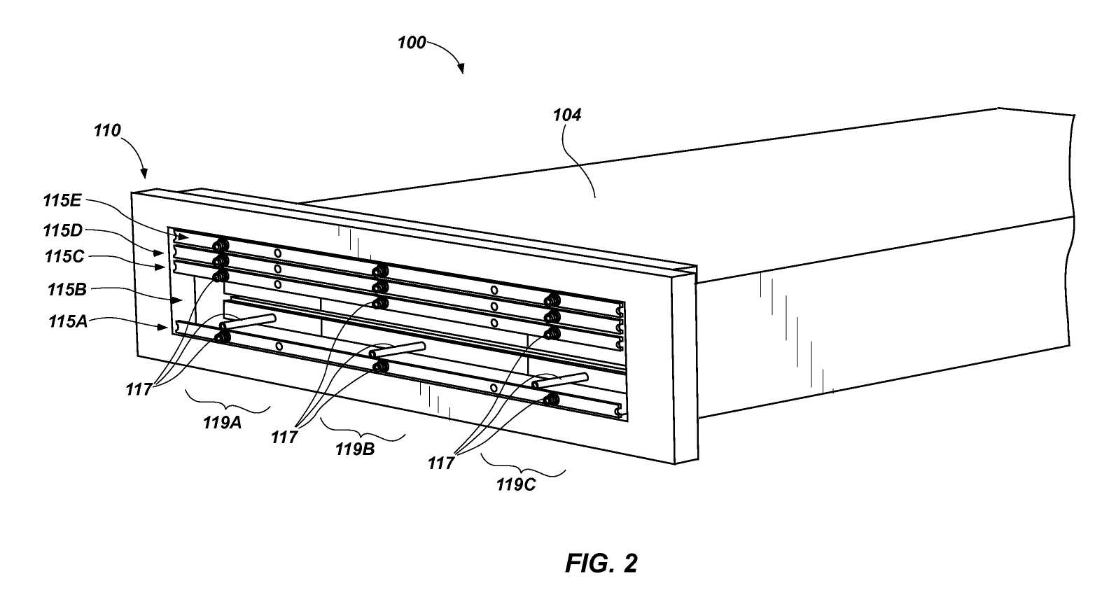

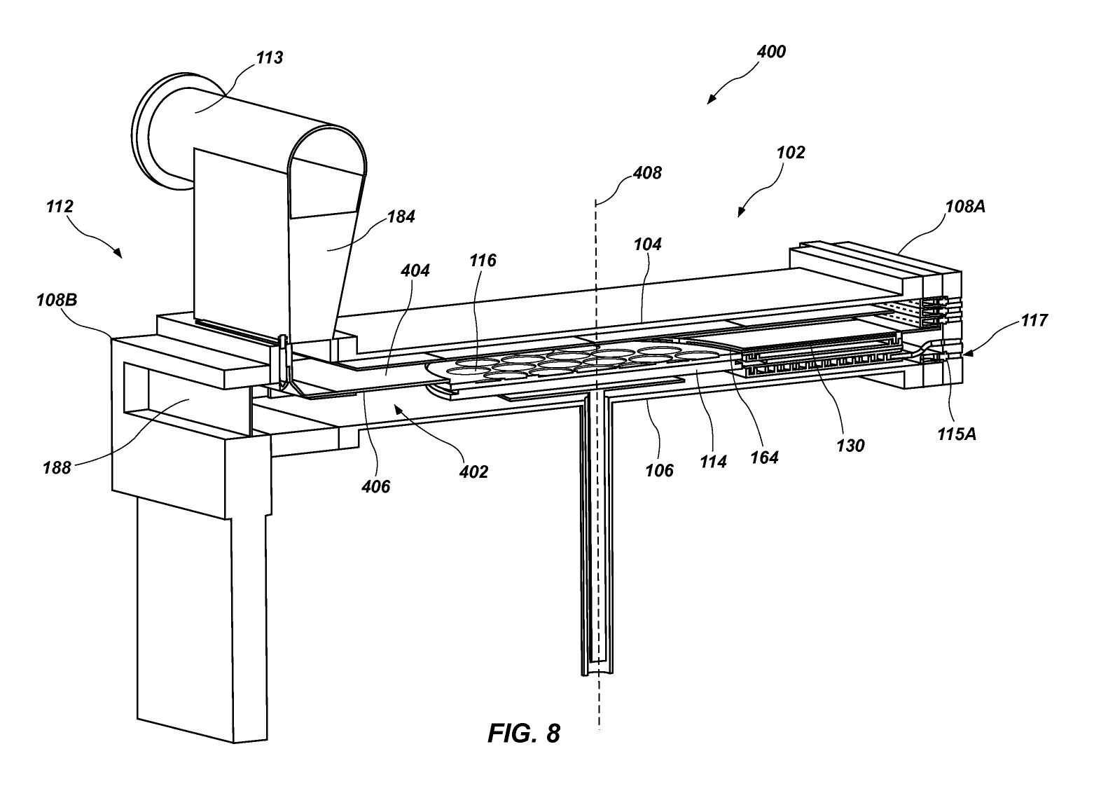

FIG. 2 is a perspective view illustrating an exterior surface of the gas injection device 110. As shown in FIG. 8, the gas injection device 110 may comprise a plurality of connectors 117, which are configured for connection to the gas inflow conduits 120A-120E. In some embodiments, the gas injection device 110 may comprise a plurality of rows 115A-115E of the connectors 117. Each of the rows 115A-115E may be configured to inject respective process gases into the reaction chamber 102. For example, the connectors 117 in a first bottom row 115A may be used for injecting a purge gas into the reaction chamber 102, the connectors 117 in a second row 115B may be used for injecting a precursor gas (e.g., GaCl₃) into the reaction chamber 102, the connectors 117 in a third row 115C may be used for injecting another precursor gas (e.g., NH₃) into the reaction chamber 102, the connectors 117 in a fourth row 115D may be used for injecting another process gas (e.g., SiH₄) into the reaction chamber 102, and the connectors 117 in a top fifth row 115E may be used for injecting a purge gas or a carrier gas (e.g., N₂) into the reaction chamber 102. The connectors 117 may be grouped into separate zones 119A-119C of connectors 117, each zone 119A-119C including connectors 117 from each of the rows 115A-115E. The connectors 117 in each zone 119A-119C may be used to convey process gases to different zones within the reaction chamber 102, thereby allowing differing process gas compositions and/or concentrations to be introduced into different regions within the reaction chamber 102 over the workpiece substrate 116.

Referring again to FIG. 1, the venting and loading subassembly 112 may comprise a vacuum chamber 184 into which gases flowing through the reaction chamber 102 are drawn by the vacuum and vented out from the reaction chamber 102. The vacuum within the vacuum chamber 184 is generated by the vacuum device 113. As shown in FIG. 1, the vacuum chamber 184 may be located below the reaction chamber 102.

The venting and loading subassembly 112 may further comprise a purge gas curtain device 186 that is configured and oriented to provide a generally planar curtain of flowing purge gas, which flows out from the purge gas curtain device 186 and into the vacuum chamber 184. The venting and loading subassembly 112 also may include an access gate 188, which may be selectively opened for loading and/or unloading workpiece substrates 116 from the substrate support structure 114, and selectively closed for processing of the workpiece substrates 116 using the deposition system 100. In some embodiments, the access gate 188 may comprise at least one plate configured to move between a closed first position and an open second position. The access gate 188 may extend through a side wall of the reaction chamber 102 remote from a side wall through which the one or more process gases are injected.

The reaction chamber 102 may be at least substantially enclosed, and access to the substrate support structure 114 through the access gate 188 may be precluded, when the plate of the access gate 188 is in the closed first position. Access to the substrate support structure 114 may be enabled through the access gate 188 when the plate of the access gate 188 is in the open second position.

The purge gas curtain emitted by the purge gas curtain device 186 may reduce or prevent the flow of gases out from the reaction chamber 102 during loading and/or unloading of workpiece substrates 116.

Gaseous byproducts, carrier gases, and any excess precursor gases may be exhausted out from the reaction chamber 102 through the venting and loading subassembly 112.

The access gate 188 may be located remote from the first location 103A at which one or more process gases are injected into the reaction chamber 102. In some embodiments, the first location 103A may be disposed on a first side of the substrate support structure 114, and the second location 103B at which process gases are evacuated out from the reaction chamber 102 through the vacuum device 113 may be disposed on an opposing second side of the support structure 114, as shown in FIG. 1. Additionally, the second location 103B at which process gases are evacuated out from the reaction chamber 102 may be disposed between the substrate support structure 114 and the access gate 188. The purge gas curtain device 186 may be configured to form a curtain of flowing purge gas that flows between the purge gas injection device and the vacuum device 113, as previously discussed. The curtain of flowing purge gas may be disposed between the substrate support structure 114 and the access gate 188, so as to form a barrier of flowing purge gas that separates the workpiece substrates 116 from the access gate 188. Such a barrier of flowing purge gas may reduce or prevent process gases from escaping out from the reaction chamber 102 when the access gate 188 is open.

In some embodiments, the gas injection system 100 may include at least one internal precursor gas furnace 130 disposed within the reaction chamber 102. The internal precursor gas furnace 130 may be configured for heating at least one precursor gas and conveying the at least one precursor gas within the reaction chamber 102 from the gas injection device 110 to a location proximate the substrate support structure 114.

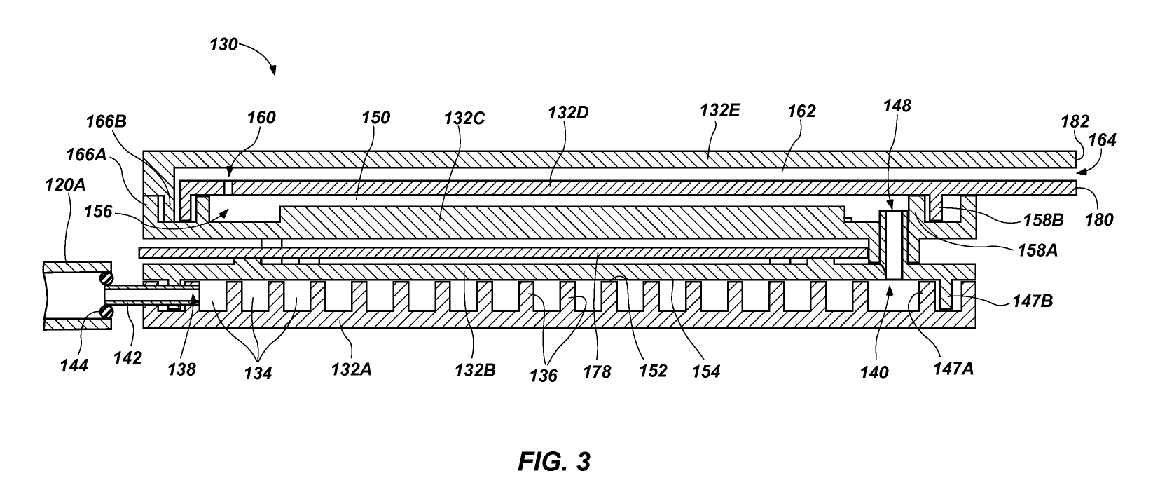

FIG. 3 is a cross-sectional side view of the precursor gas furnace 130 of FIG. 1. The furnace 130 of the embodiment of FIGS. 1 and 2 comprises five (5) generally plate-shaped structures 132A-132E that are attached together and are sized and configured to define one or more precursor gas flow paths extending through the furnace 130 in chambers defined between the generally plate-shaped structures 132A-132E. The generally plate-shaped structures 132A-132E may comprise, for example, transparent quartz so as to allow radiative energy emitted by the heating elements 118 to pass through the structures 132A-132E and heat precursor gas or gases in the furnace 130.

As shown in FIG. 3, the first plate-shaped structure 132A and the second plate-shaped structure 132B may be coupled together to define a chamber 134 therebetween. A plurality of integral ridge-shaped protrusions 136 on the first plate-shaped structure 132A may subdivide the chamber 134 into one or more flow paths extending from an inlet 138 into the chamber 134 to an outlet 140 from the chamber 134.

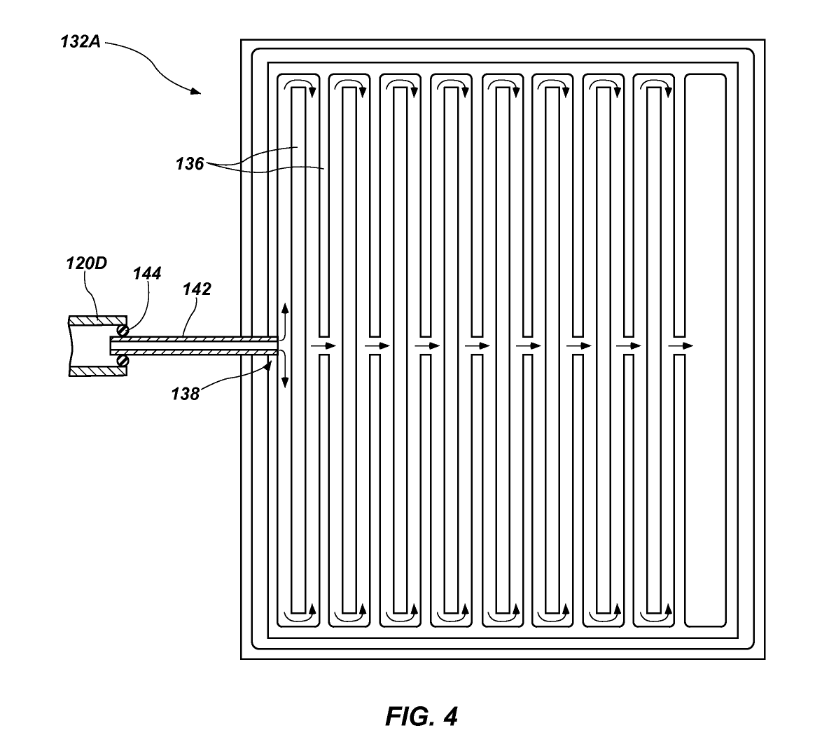

FIG. 4 is a top plan view of the first plate-shaped structure 132 and illustrates the ridge-shaped protrusions 136 thereon and the flow paths that are defined in the chamber 134 thereby. As shown in FIG. 4, the protrusions 136 define sections of the flowpath extending through the furnace 130 (FIG. 3) that have a serpentine configuration. The protrusions 136 may comprise alternating walls having apertures 138 therethough at the lateral ends of the protrusions 136 and at the center of the protrusions 136, as shown in FIG. 4. Thus, in this configuration, gases may enter the chamber 134 proximate a central region of the chamber 134 as shown in FIG. 4, flow laterally outward toward the lateral sides of the furnace 130, through apertures 138 at the lateral ends of one of the protrusions 136, back toward the central region of the chamber 134, and through another aperture 138 at the center of another protrusion 136. This flow pattern is repeated until the gases reach an opposing side of the plate 132A from the inlet 138 after flowing through the chamber 134 back and forth in a serpentine manner.

By causing one or more precursor gases to flow through this section of the flow path extending through the furnace 130, the residence time of the one or more precursor gases within the furnace 130 may be selectively increased.

Referring again to FIG. 1, the inlet 138 leading into the chamber 134 may be defined by, for example, a tubular member 142. One of the gas inflow conduits 120A-120E, such as the gas inflow conduit 120B, may extend to and couple with the tubular member 142, as shown in FIG. 1. A seal member 144, such as a polymeric O-ring, may be used to form a gas-tight seal between the gas inflow conduit 120B and the tubular member 142. The tubular member 142 may comprise, for example, opaque quartz material so as to prevent thermal energy emitted from the heating elements 118 from heating the seal member 144 to elevated temperatures that might cause degradation of the seal member 144. Additionally, the cooling of the gas injection device 110 using flow of cooling fluid through the cooling conduits 111 may prevent excessive heating and resulting degradation of the seal member 144. By maintaining the temperature of the seal member 144 below about 200° C., an adequate seal may be maintained between one of the gas inflow conduits 120A-120E and the tubular member 142 using the seal member 144 when the gas inflow conduit comprises a metal or metal alloy (e.g., steel) and the tubular member 142 comprises a refractory material such as quartz. The tubular member 142 and the first plate-shaped structure 132A may be bonded together so as to form a unitary, integral quartz body.

As shown in FIGS. 2 and 3, the plate-shaped structures 132A, 132B may include complementary sealing features 147A, 147B (e.g., a ridge and a corresponding recess) that extend about the periphery of the plate-shaped structures 132A, 132B and at least substantially hermetically seal the chamber 134 between the plate-shaped structures 132A, 132B. Thus, gases within the chamber 134 are prevented from flowing laterally out from the chamber 134, and are forced to flow from the chamber 134 through the outlet 140 (FIG. 3).

Optionally, the protrusions 136 may be configured to have a height that is slightly less than a distance separating the surface 152 of the first plate-shaped structure 132A from which the protrusions 136 extend and the opposing surface 154 of the second plate-shaped structure 132B. Thus, a small gap may be provided between the protrusions 136 and the surface 154 of the second plate-shaped structure 132B. Although a minor amount of gas may leak through these gaps, this small amount of leakage will not detrimentally affect the average residence time for the precursor gas molecules within the chamber 134. By configuring the protrusions 136 in this manner, variations in the height of the protrusions 136 that arise due to tolerances in the manufacturing processes used to form the plate-shaped structures 132A, 132B can be accounted for, such that protrusions 136 that are inadvertently fabricated to have excessive height do not prevent the formation of an adequate seal between the plate-shaped structures 132A, 132B by the complementary sealing features 147A, 147B.

As shown in FIG. 3, the outlet 140 from the chamber 134 between the plate-shaped structures 132A, 132B leads to an inlet 148 to a chamber 150 between the third plate-shaped structure 132C and the fourth plate-shaped structure 132D. The chamber 150 may be configured such that the gas or gases therein flow from the inlet 148 toward an outlet 156 from the chamber 150 in a generally linear manner. For example, the chamber 150 may have a cross-sectional shape that is generally rectangular and uniform in size between the inlet 148 and the outlet 156. Thus, the chamber 150 may be configured to render the flow of gas or gases more laminar, as opposed to turbulent.

The plate-shaped structures 132C, 132D may include complementary sealing features 158A, 158B (e.g., a ridge and a corresponding recess) that extend about the periphery of the plate-shaped structures 132C, 132D and at least substantially hermetically seal the chamber 150 between the plate-shaped structures 132C, 132D. Thus, gases within the chamber 150 are prevented from flowing laterally out from the chamber 150, and are forced to flow from the chamber 150 through the outlet 156.

The outlet 156 may comprise, for example, an elongated aperture (e.g., a slot) extending through the plate-shaped structure 132D proximate an opposing end thereof from the end that is proximate the inlet 148.

With continued reference to FIG. 3, the outlet 156 from the chamber 150 between the plate-shaped structures 132C, 132D leads to an inlet 160 to a chamber 162 between the fourth plate-shaped structure 132D and the fifth plate-shaped structure 132E. The chamber 162 may be configured such that the gas or gases therein flow from the inlet 160 toward an outlet 164 from the chamber 162 in a generally linear manner. For example, the chamber 162 may have a cross-sectional shape that is generally rectangular and uniform in size between the inlet 160 and the outlet 164. Thus, the chamber 162 may be configured to render the flow of gas or gases more laminar, as opposed to turbulent, in a manner like that previously described with reference to the chamber 150.

The plate-shaped structures 132D, 132E may include complementary sealing features 166A, 166B (e.g., a ridge and a corresponding recess) that extend about a portion of the periphery of the plate-shaped structures 132D, 132E and seal the chamber 162 between the plate-shaped structures 132D, 132E on all but one side of the plate-shaped structures 132D, 132E. A gap is provided between the plate-shaped structures 132D, 132E on the side thereof opposite the inlet 160, which gap defines the outlet 164 from the chamber 162. Thus, gases enter the chamber 162 through the inlet 160, flow through the chamber 162 toward the outlet 164 (while being prevented from flowing laterally out from the chamber 162 by the complementary sealing features 166A, 166B), and flow out from the chamber 162 through the outlet 164. The sections of the gas flow path or paths within the furnace 130 that are defined by the chamber 150 and the chamber 162 are configured to impart laminar flow to the one or more precursor gases caused to flow through the flow path or paths within the furnace 130, and reduce any turbulence therein.

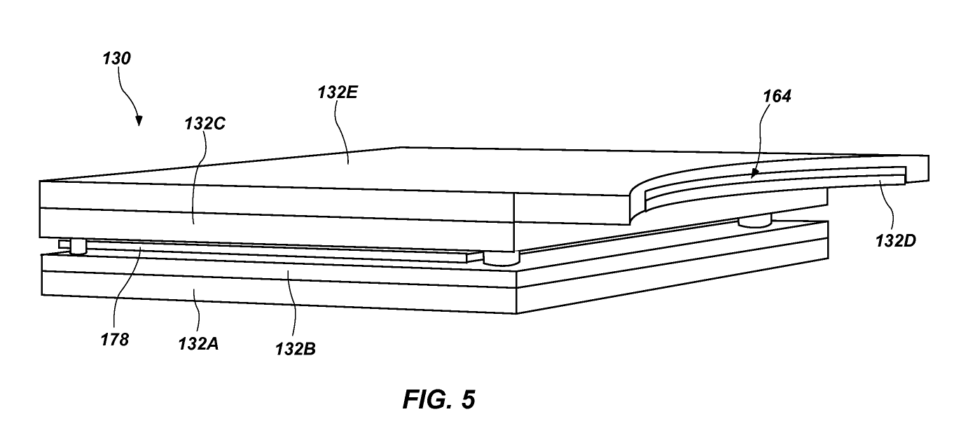

The outlet 164 is configured to output one or more precursor gases from the furnace 130 into the interior region within the reaction chamber 102. FIG. 5 is a perspective view of the furnace 130, and illustrates the outlet 164. As shown in FIG. 5, the outlet 164 may have a rectangular cross-sectional shape, which may assist in preserving laminar flow of the precursor gas or gases being injected out from the furnace 130 and into the interior region within the reaction chamber 102. The outlet 164 may be sized and configured to output a sheet of flowing precursor gas in a transverse direction over an upper surface 168 of the substrate support structure 114. As shown in FIG. 5, the end surface 180 of the fourth generally plate-shaped structure 132D and the end surface 182 of the fifth generally plate-shaped structure 132E, a gap between which defines the outlet 164 from the chamber 162 as previously discussed, may have a shape that generally matches a shape of a workpiece substrate 116 supported on the substrate support structure 114 and on which a material is to be deposited using the precursor gas or gases flowing out from the furnace 130. For example, in embodiments in which the workpiece substrate 116 comprises a die or wafer having a periphery that is generally circular in shape, the surfaces 180, 182 may have an arcuate shape that generally matches the profile of the outer periphery of the workpiece substrate 116 to be processes. In such a configuration, the distance between the outlet 164 and the outer edge of the workpiece substrate 116 may be generally constant across the outlet 164. In this configuration, the precursor gas or gases flowing out from the outlet 164 are prevented from mixing with other precursor gases within the reaction chamber 102 until they are located in the vicinity of the surface of the workpiece substrate 116 on which material is to be deposited by the precursor gases, and avoiding unwanted deposition of material on components of the deposition system 100.

Referring again to FIG. 1, the deposition system 100 may include heating elements 118. Heating elements 118 may comprise resistance heaters, induction heaters or radiant heaters. In certain embodiment the heating elements 118 comprise radiant heating lamps configured to radiate infrared energy. For example, the heating elements 118 may comprise a first group 170 of heating elements 118 and a second group of heating elements 172. The first group 170 of heating elements 118 may be located and configured for imparting radiant energy to the furnace 130 and heating the precursor gas therein. For example, the first group 170 of heating elements 118 may be located below the reaction chamber 102 under the furnace 130, as shown in FIG. 1. In additional embodiments, the first group 170 of heating elements 118 may be located above the reaction chamber 102 over the furnace 130, or may include both heating elements 118 located below the reaction chamber 102 under the furnace 130 and heating elements located above the reaction chamber 102 over the furnace 130. The second group 172 of heating elements 118 may be located and configured for imparting thermal energy to the substrate support structure 114 and any workpiece substrate supported thereon. For example, the second group 172 of heating elements 118 may be located below the reaction chamber 102 under the substrate support structure 114, as shown in FIG. 1. In additional embodiments, the second group 172 of heating elements 118 may be located above the reaction chamber 102 over the substrate support structure 114, or may include both heating elements 118 located below the reaction chamber 102 under the substrate support structure 114 and heating elements located above the reaction chamber 102 over the substrate support structure 114.

The first group 170 of heating elements 118 may be separated from the second group 172 of heating elements 118 by a thermally reflective or thermally insulating barrier 174. By way of example and not limitation, such a barrier 174 may comprise a gold-plated metal plate located between the first group 170 of heating elements 118 and the second group 172 of heating elements 118. The metal plate may be oriented to allow independently controlled heating of the furnace 130 (by the first group 170 of heating elements 118) and the substrate support structure 114 (by the second group 172 of heating elements 118). In other words, the barrier 174 may be located and oriented to reduce or prevent heating of the substrate support structure 114 by the first group 170 of heating elements 118, and to reduce or prevent heating of the furnace 130 by the second group 172 of heating elements 118.

The first group 170 of heating elements 118 may comprise a plurality of rows of heating elements 118, which may be controlled independently from one another. In other words, the thermal energy emitted by each row of heating elements 118 may be independently controllable. The rows may be oriented transverse to the direction of the net flow of gas through the reaction chamber 102, which is the direction extending from left to right from the perspective of FIG. 1. Thus, the independently controlled rows of heating elements 118 may be used to provide a selected thermal gradient across the furnace 130, if so desired. Similarly, the second group 172 of heating elements 118 also may comprise a plurality of rows of heating elements 118, which may be controlled independently from one another. Thus, a selected thermal gradient also may be provided across the substrate support structure 114, if so desired.

Optionally, passive heat transfer structures (e.g., structures comprising materials that behave similarly to a black body) may be located adjacent or proximate to at least a portion of the precursor gas furnace 130 within the reaction chamber 102 to improve transfer of heat to the precursor gases within the furnace 130.

Passive heat transfer structures (e.g., structures comprising materials that behave similarly to a black body) may be provided within the reaction chamber 102 as disclosed in, for example, U.S. Patent Application Publication No. US 2009/0214785 A1, which published on Aug. 27, 2009 in the name of Arena et al., the entire disclosure of which is incorporated herein by reference.

By way of example and not limitation, the deposition system 100 may include one or more passive heat transfer plates 177 within the reaction chamber 102, as shown in FIG. 1. These passive heat transfer plates 177 may be generally planar and may be oriented generally parallel to the top wall 104 and the bottom wall 106. In some embodiments, these passive heat transfer plates 177 may be located closer to the top wall 104 than the bottom wall 106, such that they are positioned in a plane vertically above a plane in which the workpiece substrate 116 is disposed within the reaction chamber 102. The passive heat transfer plates 177 may extend across only a portion of the space within the reaction chamber 102, as shown in FIG. 1, or they may extend across substantially the entire space within the reaction chamber 102. In some embodiments, a purge gas may be caused to flow through the reaction chamber 102 in the space between the top wall 104 of the reaction chamber 102 and the one or more passive heat transfer plates 177 so as to prevent unwanted deposition of material on the inner surface of the top wall 104 within the reaction chamber 102. Such a purge gas may be supplied from, for example, the gas inflow conduit 120A. Of course, passive heat transfer plates having configurations other than those of the heat transfer plates 177 of FIG. 1 may be incorporated within the reaction chamber 102 in additional embodiments, and such heat transfer plates may be located in positions other than those at which the heat transfer plates 177 of FIG. 1 are located.

As another non-limiting example, the precursor gas furnace 130 may include a passive heat transfer plate 178, which may be located between the second plate-shaped structure 132B and the third plate-shaped structure 132C, as shown in FIG. 3. Such a passive heat transfer plate 178 may improve the transfer of heat provided by the heating elements 118 to the precursor gas within the furnace 130, and may improve the homogeneity and consistency of the temperature within the furnace 130. The passive heat transfer plate 178 may comprise a material with high emissivity values (close to unity) (black body materials) that is also capable of withstanding the high temperature, corrosive environment that may be encountered within the reaction chamber 102. Such materials may include, for example, aluminum nitride (AlN), silicon carbide (SiC), and boron carbide (B₄C), which have emissivity values of 0.98, 0.92, and 0.92, respectively. Thus, the passive heat transfer plate 178 may absorb thermal energy emitted by the heating elements 118, and reemit the thermal energy into the furnace 130 and the precursor gas or gases therein.

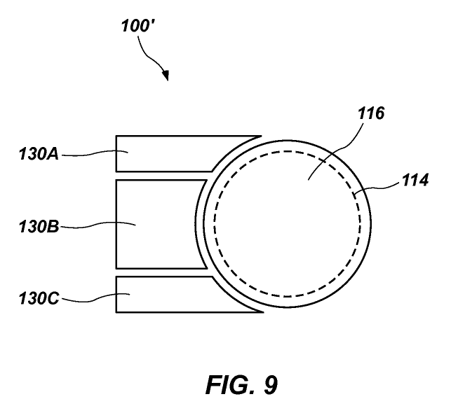

FIG. 9 is a schematic diagram illustrating a plan view of another embodiment of a deposition system 100′ that similar to the deposition system 100 of FIG. 1, but which includes three precursor gas furnaces 130A, 130B, 130C located within an interior region of the reaction chamber 102. Thus, each of the precursor gas furnaces 130A, 130B, 130C may be used for injecting different precursor gases into the reaction chamber 102. By way of example and not limitation, the precursor gas furnace 130B may be used to inject GaCl₃ into the reaction chamber 102, the precursor gas furnace 130A may be used to inject InCl₃ into the reaction chamber 102, and the precursor gas furnace 130C may be used to inject AlCl₃ into the reaction chamber 102. Optionally, a group III element precursor gas may be injected into the reaction chamber 102 using the precursor gas furnace 130B for deposition of a III-V semiconductor material, and the precursor gas furnaces 130A, 130C may be used to inject one or more precursor gases used for depositing one or more dopant elements into the III-V semiconductor material.

Embodiments of depositions systems as described herein, such as the deposition system 100 of FIG. 1 and the deposition system 100′ of FIG. 9 may enable the introduction of relatively large quantities of high temperature precursor gases into the reaction chamber 102 while maintaining the precursor gases spatially separated from one another until the gases are located in the immediate vicinity of the workpiece substrate 116 onto which material is to be deposited, which may improve the efficiency in the utilization of the precursor gases.

Previously known deposition systems (e.g., HVPE deposition systems) have commonly resulted in the formation of reaction products on surfaces within the reaction chamber 102 other than the surface of the workpiece substrate 116 on which material is to be deposited. Over time, such unwanted deposition of material may lead to increased particulate levels within the reaction chamber 102 and an associated decrease in the quality of the material deposited on the workpiece substrate 116 and inefficient heating of the reaction chamber 102 by the heating elements 118. For example, GaCl₃ condenses from the vapor phase at temperatures below about 500° C., and gallium may be deposited from GaCl₃ on surfaces in contact with the GaCl₃ vapor that are not maintained at temperatures above the vaporization temperature. Additionally, GaCl₃ is typically converted to GaCl in the reaction chamber, and the Ga is deposited from the GaCl vapor. The GaCl species is energetically favorable over the GaCl₃ species at temperatures above about 730° C. Thus, the precursor gas furnace 130 may be used to heat the precursor gas flowing therethrough to a temperature above about 730° C. prior to injecting the precursor gas over the surface of the workpiece substrate 116 on which it is desired to deposit material.

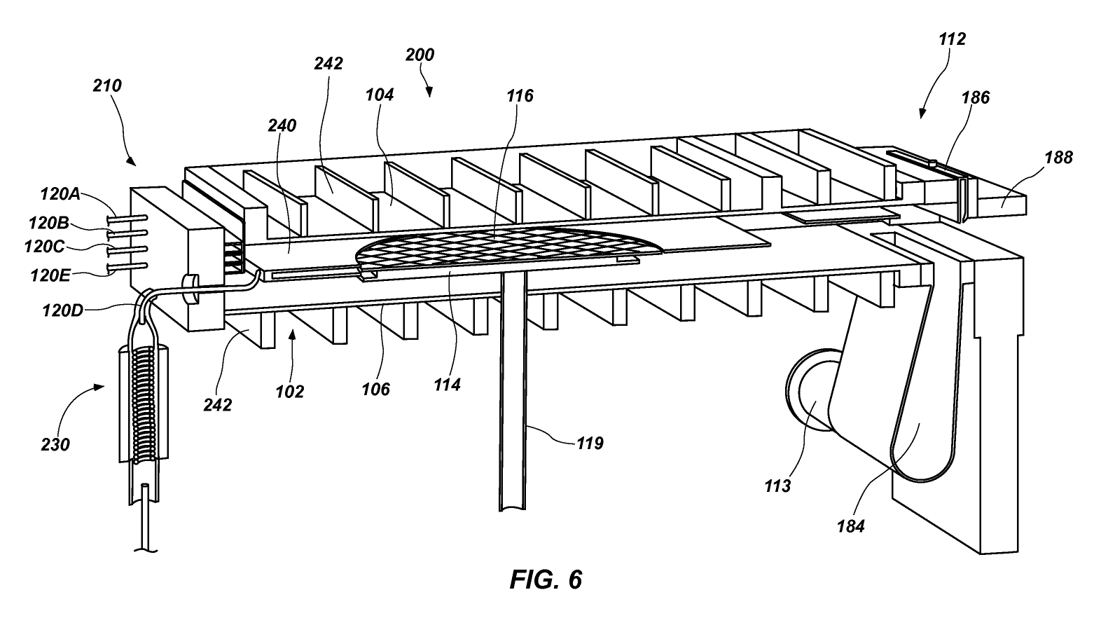

FIG. 6 is a cut-away perspective view schematically illustrating another example embodiment of a deposition system 200. The deposition system 200 is similar to the deposition system 100 of FIG. 1, and includes an access gate 188 (shown in the open position in FIG. 6), which is located remotely from a location at which process gases are injected into the reaction chamber 102. The deposition system 200, however, does not include an internal precursor gas furnace 130, but rather includes an external precursor gas injector 230 located outside the reaction chamber 102. The external precursor gas injector 230 may be configured for heating at least one precursor gas and conveying the at least one precursor gas from a precursor gas source to a gas injection device 210, which may be substantially similar to the gas injection device 110 of FIG. 1.

By way of example and not limitation, the external precursor gas injector 230 may comprise a precursor gas injector as described in any of provisional U.S. Patent Application Ser. No. 61/416,525, filed Nov. 23, 2010 and entitled “Methods of Forming Bulk III-Nitride Materials on Metal-Nitride Growth Template Layers, and Structures formed by Such Methods,” U.S. Patent Application Publication No. US 2009/0223442 A1, which published Sep. 10, 2009 in the name of Arena et al., International Publication Number WO 2010/101715 A1, published Sep. 10, 2010 and entitled “Gas Injectors for CVD Systems with the Same,” U.S. patent application Ser. No. 12/894,724, which was filed Sep. 30, 2010 in the name of Bertran, and U.S. patent application Ser. No. 12/895,311, which was filed Sep. 30, 2010 in the name of Werkhoven, the disclosures of which are hereby incorporated herein in their entireties by this reference.

The gas injector 230 may comprise a thermalizing gas injector including an elongated conduit, which may have a coiled configuration, a serpentine configuration, etc., in which the one or more process gases flowing therethrough (e.g., a precursor gas) are heated as they flow through the elongated conduit. External heating elements may be used to heat the process gas or gasses as they flow through the elongated conduit. Optionally, one or more passive heating structures (like those previously described herein) may be incorporated into the gas injector 230 to improve the heating of the process gas or gasses flowing through the gas injector 230.

Optionally, the gas injector 230 may further include a reservoir configured to hold a liquid reagent for reacting with a process gas (or a decomposition or reaction product of a process gas). For example, the reservoir may be configured to hold a liquid metal or other element, such as, for example, liquid gallium (Ga), liquid aluminum (Al), or liquid indium (In). In further embodiments of the invention, the reservoir may be configured to hold a solid reagent for reacting with a process gas (or a decomposition or reaction product of a process gas). For example, the reservoir may be configured to hold a solid volume of one or more materials, such as, for example, solid silicon (Si) or solid magnesium (Mg).

With continued reference to FIG. 6, the process gas or gases that are injected into the reaction chamber 102 from the external precursor gas injector 230 may be carried through an interior region within the reaction chamber 102 within an enclosure 140 to a location proximate the workpiece support structure 114, so as to avoid such process gas or gases from mixing with other process gas or gasses until they are in the vicinity of a workpiece substrate 116 supported on the substrate support structure 114.

In additional embodiments, the deposition systems may include both an internal precursor gas furnace 130 as described with reference to FIG. 1, as well as an external precursor gas injector 230, as described with reference to FIG. 6. For example, enclosure 240 shown in FIG. 6 could be replaced with the internal precursor gas furnace 130 of FIG. 1.

As shown in FIG. 6, the reaction chamber 102 may further include structural support ribs 242, which may be used to provide structural rigidity to the reaction chamber 102. Such support ribs 242 may be comprise a refractory material like that of the top wall 104 and bottom wall 106 of the reaction chamber 102. The reaction chamber 102 of FIG. 1 could also include such structural support ribs 242 in additional embodiments.

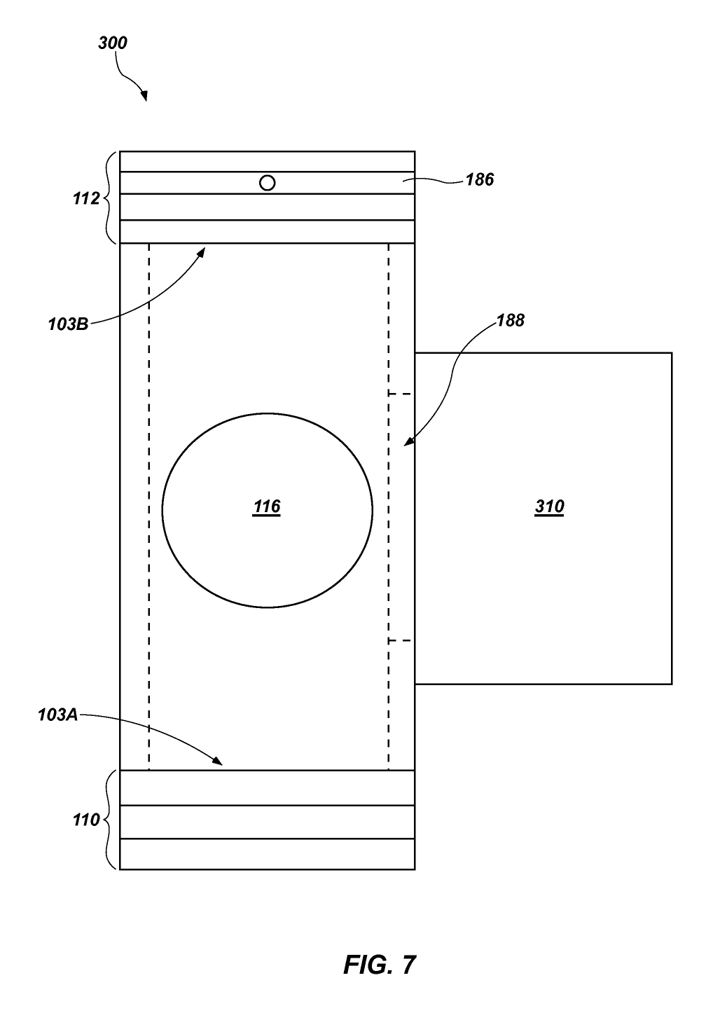

FIG. 7 schematically illustrates a top plan view of an additional example embodiment of a deposition system 300 of the present disclosure. The deposition system 300 may be substantially similar to the deposition system 100 of FIG. 1 or the deposition system 200 of FIG. 6, except that the access gate 188 is located on a lateral side of the reaction chamber 102 longitudinally between the first longitudinal end of the reaction chamber 102 near the location 103A at which one or more process gases into the reaction chamber 102 and the second longitudinal end of the reaction chamber 102 near the location 103B at which the process gases are vented out from the reaction chamber 102. In other words, in the deposition system 300 of FIG. 7, the workpiece substrates 116 may be loaded and unloaded along a direction transverse to the generally direction of gas flow through the reaction chamber 102. Thus, the access gate 188 is located remotely from the location 103A at which process gases are injected into the reaction chamber 102, as is the access gate 188 in the embodiments of FIGS. 1 and 6.

As shown in FIG. 7, the deposition system 300 further includes at least one robotic arm device 310 configured to robotically load workpiece substrates 116 into the reaction chamber 102 through the access gate 188 and to unload workpiece substrates 116 out from the reaction chamber 102 through the access gate 188. Such robotic arm devices are known in the art. Although not illustrated in FIGS. 1 and 6, the deposition system 100 of FIG. 1 and the deposition system 200 of FIG. 6 also may include at least one such robotic arm device 310 configured to robotically load workpiece substrates 116 into the reaction chamber 102 through the access gate 188 and to unload workpiece substrates 116 out from the reaction chamber 102 through the access gate 188.

FIG. 8 schematically illustrates a view of an additional example embodiment of a deposition system 400 of the present disclosure. The deposition system 400 may be substantially similar to the deposition system 100 of FIG. 1 or the deposition system 200 of FIG. 6, except that the reaction chamber 102 may be divided into two or more channels. In some embodiments, the two or more channels may be disposed vertically over one another. For example, the two or more channels may comprise a load/unload channel 402 and an injection/exhaust channel 404. The load/unload channel 402 may be located within reaction chamber 102 between a rear intermediate shelf 406 and the bottom wall 106, and the injection/exhaust channel 404 may be located within reaction chamber 102 between the rear intermediate shelf 406/ and the top wall 104.

The injection/exhaust channel 404 is in fluidic connection to the vacuum device 113 through vacuum chamber 184 for exhausting gaseous byproducts, carrier gases, and any excess precursor gases out from the reaction chamber 102.

The load/unload channel 402 may extend to an access gate 188, which may be selectively opened for loading and/or unloading workpiece substrates 116 from the substrate support structure 114 and/or the substrate support structure 114 through the load/unload channel 402. The access gate 188 may be selectively closed for processing of the workpiece substrates 116 using the deposition system 400. In addition, the load/unload channel 402 may be in fluidic connection with a first bottom row 115A of connectors 117 for injecting process gas. In this configuration, a purge gas may be injected into the load/unload channel 402 to prevent gaseous byproducts, carrier gases, and any excess precursor gases from entering load/unload channel 402, thereby reducing (e.g., preventing) parasitic deposition of material upon the access gate 188.

For loading/unloading processes, at least one robotic arm device (not illustrated in FIG. 8) may be configured to traverse back and forth through the load/unload channel 402 to enable robotically automated loading of workpiece substrates 116 (and/or a substrate support structure 114) into the reaction chamber 102 through the access gate 188, and to enable robotically automated unloading of workpiece substrates 116 (and/or substrate support structures 114) out from the reaction chamber 102 through the access gate 188. Such robotic arm devices are known in the art.

The substrate support structure 114 and workpiece substrates 116 located thereon may be raised and lowered along the axis of rotation 408 of the substrate support structure 114. A drive (not shown) may be coupled to the spindle 119 to enable movement of the substrate support structure 114 and the workpiece substrates 116 located thereon along the axis of rotation 408 (in additional to rotation of the substrate support structure 114 and the workpiece substrates 116 about the axis of rotation 408).

The substrate support structure 114 and workpiece substrates 116 located thereon may be raised to a deposition position and lowered to a load/unload position within the reaction chamber 102 to enable deposition processes and loading/unloading processes, respectively. For deposition processes, the substrate support structure 114 may be raised to a deposition position at which the substrate support structure 114 may be located within or at least adjacent to the injection/exhaust channel 404, and, more specifically, substantially coplanar with the rear intermediate shelf 406. For load/unload processes, the substrate support structure 114 may be lowered to a load/unload position at which the substrate support structure 114 may be located within the load/unload channel 404, and, more specifically, may be located proximate to the bottom wall 106.

Embodiments of depositions systems as described herein, such as the depositions system 100 of FIG. 1, the deposition system 200 of FIG. 6, the deposition system 300 of FIG. 7, and the deposition system 400 of FIG. 8 may be used to deposit semiconductor material on a workpiece substrate 116 in accordance with further embodiments of the disclosure.

Referring to FIG. 1, a workpiece substrate 116 may be loaded into a reaction chamber 102 and onto a substrate support structure 114 through at least one access gate 188. One or more process gases, which may include one or more precursor gases, may be caused to flow into the reaction chamber 102 through at least one gas injection device 110 located remote from the at least one access gate 188. One or more process gases may be evacuated out from the reaction chamber 102 through at least one vacuum device 113, which may be located on an opposing side of the substrate support structure 114 from the at least one gas injection device 110. A surface of the workpiece substrate 116 may be exposed to the one or more process gases as they flow from the at least one gas injection device 110 to the at least one vacuum device 113, and semiconductor material may be deposited on the surface of the workpiece substrate 114.

In some embodiments, the access gate 188 through which the workpiece substrate 116 is loaded and unloaded may be located on a side of the vacuum device 113 opposite the at least one gas injection device 110, as previously discussed.

Additionally, a curtain of flowing purge gas may be formed using the purge gas curtain device 186, as previously described. The curtain of flowing purge gas may be disposed between the substrate support structure 114 and the access gate 188.

In some embodiments, the process gases may comprise at least precursor gases selected to include a group III element precursor gas and a group V element precursor gas. In such embodiments, the semiconductor material to be deposited on the workpiece substrate 114 may comprise a III-V semiconductor material. The group III element precursor gas optionally may be caused to flow through at least one precursor gas flow path extending through the precursor gas furnace 130 disposed within the reaction chamber 102 to heat the group III element precursor gas.

The group III element precursor gas may comprise one or more of GaCl₃, InCl₃, and AlCl₃. In such embodiments, the heating of the group III element precursor gas may result in decomposition of at least one of GaCl₃, InCl₃, and AlCl₃ to farm at least one of GaCl, InCl, AlCl, and a chlorinated species (e.g., HCl).

After heating the group III element precursor gas within the furnace 130, the group V element precursor gas and the group III element precursor gas may be mixed together within the reaction chamber 102 over the workpiece substrate 116. The surface of the workpiece substrate 116 may be exposed to the mixture of the group V element precursor gas and the group III element precursor gas to form a III-V semiconductor material on the surface of the workpiece substrate 116.

Similar methods according to the present disclosure may be performed using the deposition system 200 of FIG. 6.

Methods of the present disclosure also include methods of fabricating deposition systems as described herein, such as the deposition system 100 of FIG. 1 and the deposition system 200 of FIG. 6. A reaction chamber 102 may be formed that includes a top wall 104, a bottom wall 106, and at least one side wall 108A, 108B. A substrate support structure 114 for supporting at least one workpiece substrate 116 may be provided at least partially within the reaction chamber 102. At least one gas injection device 110 may be coupled to the reaction chamber at a first location 103A. The gas injection device may be configured for injecting one or more process gases into the reaction chamber 102 at the first location 103A. The one or more process gases may include at least one precursor gas. At least one vacuum device 113 also may be coupled to the reaction chamber 102 at a second location. The vacuum device 113 may be configured for drawing the process gas or gasses through the reaction chamber 102 from the first location 103A to the second location 103B and for evacuating the process gas or gases out from the reaction chamber 102 at the second location 103B.

At least one access gate 188 may be coupled to the reaction chamber 102 at a location remote from the first location 103A at which the gas injection device 110 is coupled to the reaction chamber 102. The at least one access gate 188 may be configured to enable a workpiece substrate 116 to be loaded into the reaction chamber 102 and onto the substrate support structure 114, and unloaded from the substrate support structure 114 out from the reaction chamber 102 through the at least one access gate 188.

Additional non-limiting example embodiments of the invention are described below.

### Embodiment 1

A deposition system, comprising: a reaction chamber defined by a top wall, a bottom wall, and at least one side wall; a substrate support structure disposed at least partially within the reaction chamber and configured to support a workpiece substrate within the reaction chamber; at least one gas injection device for injecting one or more process gases including at least one precursor gas into the reaction chamber at a first location; a vacuum device for drawing the one or more process gases through the reaction chamber from the first location to a second location and for evacuating the one or more process gases out from the reaction chamber at the second location; and at least one access gate through which a workpiece substrate may be loaded into the reaction chamber and onto the substrate support structure and unloaded from the substrate support structure out from the reaction chamber, the at least one access gate located remote from the first location.

### Embodiment 2

The deposition system of Embodiment 1, wherein the first location is disposed on a first side of the substrate support structure, and the second location is disposed on an opposing second side of the substrate support structure.

### Embodiment 3

The deposition system of Embodiment 2, wherein the second location is disposed between the substrate support structure and the at least one access gate.

### Embodiment 4

The deposition system of any one of Embodiments 1 through 3, further comprising at least one purge gas injection device configured to form a curtain of flowing purge gas flowing between the at least one purge gas injection device and the vacuum device, the curtain of flowing purge gas disposed between the workpiece support structure and the at least one access gate.

### Embodiment 5

The deposition system of Embodiment 1, wherein the second location is disposed between the substrate support structure and the at least one access gate.

### Embodiment 6

The deposition system of any one of Embodiments 1 through 4, wherein the at least one gas injection device is located at a first end of the reaction chamber, and the at least one access gate is located at an opposing second end of the reaction chamber.

### Embodiment 7

The deposition system of any one of Embodiments 1 through 4, wherein the at least one gas injection device is located at a first end of the reaction chamber, and the at least one access gate is located at a lateral side of the reaction chamber.

### Embodiment 8

The deposition system of any one of Embodiments 1 through 7, wherein the at least one access gate comprises at least one plate configured to move between a closed first position and an open second position, wherein the reaction chamber is at least substantially enclosed and access to the substrate support structure through the at least one access gate is precluded when the at least one plate is in the closed first position, and wherein access to the substrate support structure is enabled through the at least one access gate when the at least one plate is in the open second position.

### Embodiment 9

The deposition system of any one of Embodiments 1 through 8, wherein the at least one gas injection device comprises a gas injection manifold.

### Embodiment 10

The deposition system of any one of Embodiments 1 through 9, further comprising at least one internal precursor gas furnace disposed within the reaction chamber, the at least one internal precursor gas furnace configured for heating at least one precursor gas and conveying the at least one precursor gas within the reaction chamber from the at least one gas injection device to a location proximate the substrate support structure.

### Embodiment 11

The deposition system of any one of Embodiments 1 through 10, further comprising at least one external precursor gas injector located outside the reaction chamber, the at least one external precursor gas injector configured for heating at least one precursor gas and conveying the at least one precursor gas from a precursor gas source to the at least one gas injection device.

### Embodiment 12

The deposition system of any one of Embodiments 1 through 11, further comprising at least one robotic arm device configured to robotically load workpiece substrates into the reaction chamber through the at least one access gate and unload workpiece substrates out from the reaction chamber through the at least one access gate.

### Embodiment 13

The deposition system of any one of Embodiments 1 through 12, wherein the at least one gas injection device for injecting one or more process gases is configured to inject the one or more process gases through at least one side wall of the reaction chamber, and wherein the at least one access gate extends through another side wall remote from the at least one side wall through which the one or more process gases are injected.

### Embodiment 14

The deposition system of Embodiment 13, wherein the at least one side wall through which the one or more process gases are injected and the another side wall are located at opposing ends of the reaction chamber.

### Embodiment 15

A method of depositing semiconductor material on a workpiece substrate using a deposition system, comprising: loading a workpiece substrate into a reaction chamber and onto a substrate support structure through at least one access gate; flowing one or more process gases into the reaction chamber through at least one gas injection device located remote from the at least one access gate, the one or more process gases including at least one precursor gas; evacuating one or more process gases out from the reaction chamber through at least one vacuum device located on an opposing side of the substrate support structure from the at least one gas injection device; exposing a surface of the workpiece substrate to the one or more process gases as they flow from the at least one gas injection device to the at least one vacuum device and depositing semiconductor material on the surface of the workpiece substrate; and unloading the workpiece substrate out from the reaction chamber through the at least one access gate.

### Embodiment 16

The method of Embodiment 15, further comprising selecting the at least one precursor gas to comprise a group III element precursor gas and a group V element precursor gas.

### Embodiment 17

The method of Embodiment 15 or Embodiment 16, wherein depositing semiconductor material on the surface of the workpiece substrate comprises depositing a III-V semiconductor material on the surface of the workpiece substrate.

### Embodiment 18

The method of any one of Embodiments 15 through 17, wherein loading the workpiece substrate into the reaction chamber and onto the substrate support structure through the at least one access gate comprises loading the workpiece substrate into the reaction chamber through at least one access gate located on a side of the at least one vacuum device opposite the at least one gas injection device.

### Embodiment 19

The method of any one of Embodiments 15 through 18, further comprising forming a curtain of flowing purge gas disposed between the workpiece support structure and the at least one access gate.

### Embodiment 20

A method of fabricating a deposition system, comprising: forming a reaction chamber including a top wall, a bottom wall, and at least one side wall; providing a substrate support structure for supporting at least one workpiece substrate at least partially within the reaction chamber; coupling at least one gas injection device to the reaction chamber at a first location, the at least one gas injection device configured for injecting one or more process gases including at least one precursor gas into the reaction chamber at the first location; coupling at least one vacuum device to the reaction chamber at a second location, the at least one vacuum device configured for drawing the one or more process gases through the reaction chamber from the first location to the second location and for evacuating the one or more process gases out from the reaction chamber at the second location; and coupling at least one access gate to the reaction chamber at a location remote from the first location, the at least one access gate configured to enable a workpiece substrate to be loaded into the reaction chamber and onto the substrate support structure and unloaded from the substrate support structure out from the reaction chamber through the at least one access gate.

### Embodiment 21

The method of Embodiment 20, further comprising locating the at least one gas injection device on a first side of the substrate support structure, and locating the at least one vacuum device on an opposing second side of the substrate support structure.

### Embodiment 22

The method of Embodiment 20 or Embodiment 21, further comprising locating the at least one vacuum device between the substrate support structure and the at least one access gate.

### Embodiment 23

The method of any one of Embodiments 20 through 22, further comprising coupling at least one purge gas injection device to the reaction chamber proximate the at least one vacuum device, the at least one purge gas injection device configured to form a curtain of purge gas flowing from the at least one purge gas injection device to the at least one vacuum device between the substrate support structure and the at least one access gate.

### Embodiment 24

The method of any one of Embodiments 20 through 23, further comprising locating the at least one vacuum device between the substrate support structure and the at least one access gate.

### Embodiment 25

The method of any one of Embodiments 20 through 24, further comprising locating the at least one gas injection device at a first end of the reaction chamber, and locating the at least one access gate at an opposing second end of the reaction chamber.

The embodiments of the invention described above do not limit the scope the invention, since these embodiments are merely examples of embodiments of the invention, which is defined by the scope of the appended claims and their legal equivalents. Any equivalent embodiments are intended to be within the scope of this invention. Indeed, various modifications of the invention, in addition to those shown and described herein, such as alternate useful combinations of the elements described, will become apparent to those skilled in the art from the description. Such modifications are also intended to fall within the scope of the appended claims.

What is claimed is:

1. A deposition system, comprising:
a reaction chamber defined by a top wall, a bottom wall, and at least one side wall;
a substrate support structure disposed at least partially within the reaction chamber and configured to support a workpiece substrate within the reaction chamber;
at least one gas injection device for injecting one or more process gases including at least one precursor gas into the reaction chamber at a first location;
a vacuum device for drawing the one or more process gases through the reaction chamber from the first location to a second location and for evacuating the one or more process gases out from the reaction chamber at the second location; and
at least one access gate through which a workpiece substrate may be loaded into the reaction chamber and onto the substrate support structure and unloaded from the substrate support structure out from the reaction chamber, the at least one access gate located remote from the first location.

2. The deposition system of claim 1, wherein the first location is disposed on a first side of the substrate support structure, and the second location is disposed on an opposing second side of the substrate support structure.

3. The deposition system of claim 2, wherein the second location is disposed between the substrate support structure and the at least one access gate.

4. The deposition system of claim 3, further comprising at least one purge gas injection device configured to form a curtain of flowing purge gas flowing between the at least one purge gas injection device and the vacuum device, the curtain of flowing purge gas disposed between the workpiece support structure and the at least one access gate.

5. The deposition system of claim 1, wherein the second location is disposed between the substrate support structure and the at least one access gate.

6. The deposition system of claim 1, wherein the at least one gas injection device is located at a first end of the reaction chamber, and the at least one access gate is located at an opposing second end of the reaction chamber.

7. The deposition system of claim 1, wherein the at least one gas injection device is located at a first end of the reaction chamber, and the at least one access gate is located at a lateral side of the reaction chamber.

8. The deposition system of claim 1, wherein the at least one access gate comprises at least one plate configured to move between a closed first position and an open second position, wherein the reaction chamber is at least substantially enclosed and access to the substrate support structure through the at least one access gate is precluded when the at least one plate is in the closed first position, and wherein access to the substrate support structure is enabled through the at least one access gate when the at least one plate is in the open second position.

9. The deposition system of claim 1, wherein the at least one gas injection device comprises a gas injection manifold.

10. The deposition system of claim 1, further comprising at least one internal precursor gas furnace disposed within the reaction chamber, the at least one internal precursor gas furnace configured for heating at least one precursor gas and conveying the at least one precursor gas within the reaction chamber from the at least one gas injection device to a location proximate the substrate support structure.

11. The deposition system of claim 1, further comprising at least one external precursor gas injector located outside the reaction chamber, the at least one external precursor gas injector configured for heating at least one precursor gas and conveying the at least one precursor gas from a precursor gas source to the at least one gas injection device.

12. The deposition system of claim 1, further comprising at least one robotic arm device configured to robotically load workpiece substrates into the reaction chamber through the at least one access gate and unload workpiece substrates out from the reaction chamber through the at least one access gate.

13. The deposition system of claim 1, wherein the at least one gas injection device for injecting one or more process gases is configured to inject the one or more process gases through at least one side wall of the reaction chamber, and wherein the at least one access gate extends through another side wall remote from the at least one side wall through which the one or more process gases are injected.

14. The deposition system of claim 13, wherein the at least one side wall through which the one or more process gases are injected and the another side wall are located at opposing ends of the reaction chamber.

15. A method of depositing semiconductor material on a workpiece substrate using a deposition system, comprising:
loading a workpiece substrate into a reaction chamber and onto a substrate support structure through at least one access gate;
flowing one or more process gases into the reaction chamber through at least one gas injection device located remote from the at least one access gate, the one or more process gases including at least one precursor gas;
evacuating one or more process gases out from the reaction chamber through at least one vacuum device located on an opposing side of the substrate support structure from the at least one gas injection device;
exposing a surface of the workpiece substrate to the one or more process gases as they flow from the at least one gas injection device to the at least one vacuum device and depositing semiconductor material on the surface of the workpiece substrate; and
unloading the workpiece substrate out from the reaction chamber through the at least one access gate.

16. The method of claim 15, further comprising selecting the at least one precursor gas to comprise a group III element precursor gas and a group V element precursor gas.

17. The method of claim 16, wherein depositing semiconductor material on the surface of the workpiece substrate comprises depositing a III-V semiconductor material on the surface of the workpiece substrate.

18. The method of claim 15, wherein loading the workpiece substrate into the reaction chamber and onto the substrate support structure through the at least one access gate comprises loading the workpiece substrate into the reaction chamber through at least one access gate located on a side of the at least one vacuum device opposite the at least one gas injection device.

19. The method of claim 15, further comprising forming a curtain of flowing purge gas disposed between the workpiece support structure and the at least one access gate.

20. A method of fabricating a deposition system, comprising:
forming a reaction chamber including a top wall, a bottom wall, and at least one side wall;
providing a substrate support structure for supporting at least one workpiece substrate at least partially within the reaction chamber;
coupling at least one gas injection device to the reaction chamber at a first location, the at least one gas injection device configured for injecting one or more process gases including at least one precursor gas into the reaction chamber at the first location;
coupling at least one vacuum device to the reaction chamber at a second location, the at least one vacuum device configured for drawing the one or more process gases through the reaction chamber from the first location to the second location and for evacuating the one or more process gases out from the reaction chamber at the second location; and
coupling at least one access gate to the reaction chamber at a location remote from the first location, the at least one access gate configured to enable a workpiece substrate to be loaded into the reaction chamber and onto the substrate support structure and unloaded from the substrate support structure out from the reaction chamber through the at least one access gate.

21. The method of claim 20, further comprising locating the at least one gas injection device on a first side of the substrate support structure, and locating the at least one gas vacuum device on an opposing second side of the substrate support structure.

22. The method of claim 21, further comprising locating the at least one vacuum device between the substrate support structure and the at least one access gate.

23. The method of claim 22, further comprising coupling at least one purge gas injection device to the reaction chamber proximate the at least one vacuum device, the at least one .purge gas injection device configured to form a curtain of purge gas flowing from the at least one purge gas injection device to the at least one vacuum device between the substrate support structure and the at least one access gate.

24. The method of claim 20, further comprising locating the at least one vacuum device between the substrate support structure and the at least one access gate.

25. The method of claim 20, further comprising locating the at least one gas injection device at a first end of the reaction chamber, and locating the at least one access gate at an opposing second end of the reaction chamber.
